(19) United States
(12) Patent Application Publication
(10) Pub. No.: US 2009/0057697 A1
(43) Pub. Date: Mar. 5, 2009

(54) LED ASSEMBLY WITH LED-REFLECTOR INTERCONNECT

(75) Inventor: Ronald E. Belek, Coventry, CT (US)

Correspondence Address: HOFFMANN & BARON, LLP, 6900 JERICHO TURNPIKE, SYOSSET, NY, 11791, US

(73) Assignee: HENKEL CORPORATION, Rocky Hill, CT (US)

(21) Appl. No.: 11/666,471

(22) PCT Filed: Sep. 9, 2005
(86) PCT No.: PCT/US2005/032442

§ 371 Date: Oct. 10, 2008

Related U.S. Application Data
(60) Provisional application No. 60/622,830, filed on Oct. 28, 2004.

(51) Int. Cl. H01L 33/00

(52) U.S. Cl. 257/98; 438/27; 257/E33.058; 257/E33.067

(57) ABSTRACT

The present invention provides a high output LED assembly including a heat sink (18) and an LED (14) mounted at one end of the heat sink (18). The LED (14) is in electrical engagement with the heat sink (18). The assembly also includes a conductive reflector (12b) mounted to the heat sink (18), surrounding the LED (14). An insulative member (19) is provided between the reflector and the heat sink. The assembly further includes an electrical engagement directly connecting the LED (14) to the reflector (12b) to provide an optimum connection for a high output LED assembly.

### CROSS-REFERENCE TO RELATED APPLICATIONS

This application claims the benefit of U.S. Provisional Application No. 60/622,830 filed on Oct. 28, 2004 entitled “LED ASSEMBLY WITH LED-REFLECTOR INTERCONNECT”.

### BACKGROUND OF THE INVENTION

1. Field of the Invention

The present invention relates to light emitting diode (“LED”) technology, particularly to connection of the LED to an associated reflector in a LED assembly.

2. Brief Description of Related Technology

LED assemblies are well-known and commercially available. Such assemblies are employed in a wide variety of applications, typically for the production of ultraviolet radiation, used, for example, in effecting the curing of photo initiated adhesives and coative compositions.

Several factors play into the fabrication of LED assemblies. One important factor is the connection of the reflector to the LED assembly. Typically, an aluminum reflector is press fit into the assembly. A LED chip is mounted in the assembly desirably positioned around at the center and partially or wholly surrounded by the reflector. The LED chip is further electrically isolated from the reflector. Additionally, a conductive metal pin such as a gold pin is pressed into the LED assembly. The LED is in electrical engagement with the metal pin. The pin protrudes into the optical path thus masking a small portion of the optical transmission. In addition the pin requires high precision of the pin, the hole for the pin, and difficulty in inserting the pin. One of the key elements of this connection is the fact that aluminum can be wire bonded to both gold and aluminum. Previously when the pin was inserted some of its gold was scraped off making wire bonding difficult.

One known method of fabrication of LED assembly is provided in a Patent Publication No. WO 2004/011848. This patent publication discloses a LED curing device having a LED surrounded by a reflector at one end of the device. The reflector is carved inside an insulated sleeve and a wire from the LED is bonded to the insulated sleeve with an electrically conductive adhesive. The wire is clamped into the sleeve which can damage the wire, even causing the wire to break. Additionally, the LED is mounted on a heat pipe extending from the one end to the other end of the device.

In order to overcome the above-noted disadvantages of known LED assemblies with the LED-reflector interconnect, there is a need to provide a LED assembly highly reliable, has a flexible design, easy to manufacture, and reduces assembly cost.

### SUMMARY OF THE INVENTION

In one embodiment of the present invention, there is a disclosed a LED assembly having at least one LED, and a heat sink supporting the LED in electrical engagement therewith. A conductive reflector is mounted to the heat sink and in electrical engagement with the LED. The LED is surrounded by the reflector. The reflector includes a side wall having a cut machined into a portion of the side wall. Wire is bonded from the LED to the cut on the reflector. Additionally, an insulative member electrically isolates the conductive reflector from the heat sink. The heat sink and the reflector form an electrically conductive location for supplying power to the LED.

### BRIEF DESCRIPTION OF THE DRAWINGS

FIG. 1A is a schematic cut-away side view of a LED assembly of the present invention.

FIG. 1B is a full scale view of the LED connection to the reflector of the assembly of FIG. 1A.

FIG. 2 is a schematic side view of LED electro-optic assembly of the present invention.

### DETAILED DESCRIPTION OF THE INVENTION

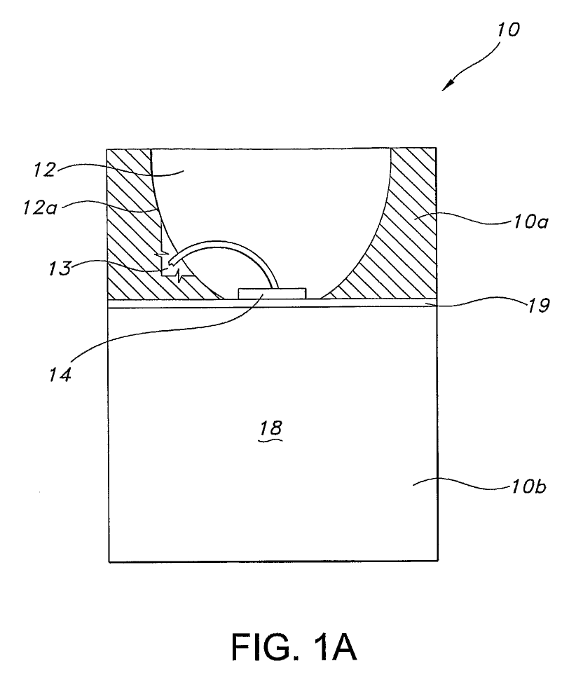

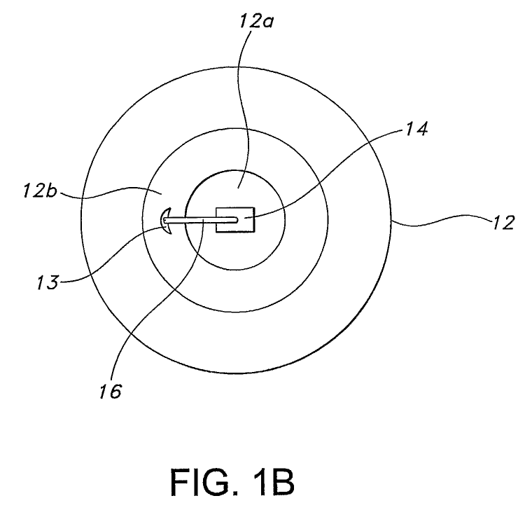

Referring to FIG. 1A of the present invention, there is shown a schematic side view of an LED assembly 10 of the present invention. The assembly 10 is divided into two contacts, i.e., electrodes, an upper electrode 10a and lower electrode 10b, both made of metal. A metal reflector 12 preferably made of aluminum is press fit into the electrode 10a. The metal reflector 12 may be shaped as a curve and functions to generally collimate and direct the LED light towards a lens and will be described in greater detail below. In a preferred embodiment, the reflector 12 is shaped elliptical having a central opening 12a, therethrough.

A LED chip 14 is mounted in the electrode 20a, desirably positioned at the central opening 12a and partially or wholly surrounded by the reflector 12 by an adhesive bond (not shown). The LED chip 14 is further electrically isolated from the reflector 12. Because metal is a good electrical conductor, both the metal reflector 12 and the metal electrode 10a provide an electrical transfer path away from the LED chip 14.

As shown in FIG. 1A, the reflector 12 includes a side wall 12b. A cut 13 is machined into a small portion of the reflector's side wall 12b. An electrical engagement such as the aluminum wire or wires 16 connects the LED 14 directly to the reflector 12. This connection of the LED 14 to the reflector 12 provides a high light output as will be described in greater detail below with reference to FIG. 1B.

When current flows through a chip in an individual LED assembly, both light and heat are generated. Increasing the current through the chip raises the light output but increased current flow also raises the temperature of the chip in the individual LED assembly. This temperature increase lowers the efficiency of the chip. Overheating is the main cause of the failure of individual LED assemblies. To assure safe operation, either the current, and as a result the light output, must be kept at a low level or some other means of transferring heat away from the chip in the individual LED assembly must be provided. Therefore, lower electrode 10b may be defined by with an electrically conducting thermal heat sink 18 which also serves to carry heat away from the LED chip 14. The upper electrode 10a and the lower electrode 10b are held together by an electrically insulating material 19 such as a non-conductive adhesive. The heat sink 18 includes a planar surface at one end and the LED 14 is mounted onto the planar surface of the heat sink 18. The LED 14 is disposed in the assembly 10 in such a manner that the bottom surface of the LED 14 is bonded or soldered to the planar surface thermal heat sink 18 via the bond material 19. In order to allow the electrical connection through the LED 14, voltage is applied to both upper and lower electrodes 10a and 10b respectively. This causes the heat sink 18 to carry off heat and the curved surface of the reflector 12 forms the light from the LED 14 into a desired pattern. Even though only single LED 14 is shown in FIG. 1, it is understood that multiple LEDs can be employed in the assembly 10.

Referring to FIG. 1B, there is shown an enlarged view of the direct connection of the LED 14 to the reflector 12 of the assembly 10 of the present invention. The LED chip 14 is mounted in the central opening 12a of the reflector as shown. As mentioned above, the reflector 12 also includes a side wall 12b with a cut 13 machined into a small portion of the side wall 12b of the reflector 12 as shown. The diameter of the cut 13 is preferably small in size preferably about 0.015 inches or less. The side wall 12b of the reflector 12 is generally parallel to flat top portion of the LED 14. An electrical engagement preferably an aluminum wire 16 bonds the LED 14 directly to the reflector 12. The aluminum wire 16 is preferably welded to the top surface of the LED chip at one end. The other end of the wire 16 is preferably soldered at the cut 13 to the side wall 12b of the reflector 12 to electrically connect the reflector 13 to the LED 14. Multiple wires 16 maybe employed to add to the reliability of this connection. Because the cut contact does not protrude into the optical path, the only block to the light output is the wire itself. This direct connection for the LED 14 to the reflector 12 provides an optimum connection for the LED assembly 10.

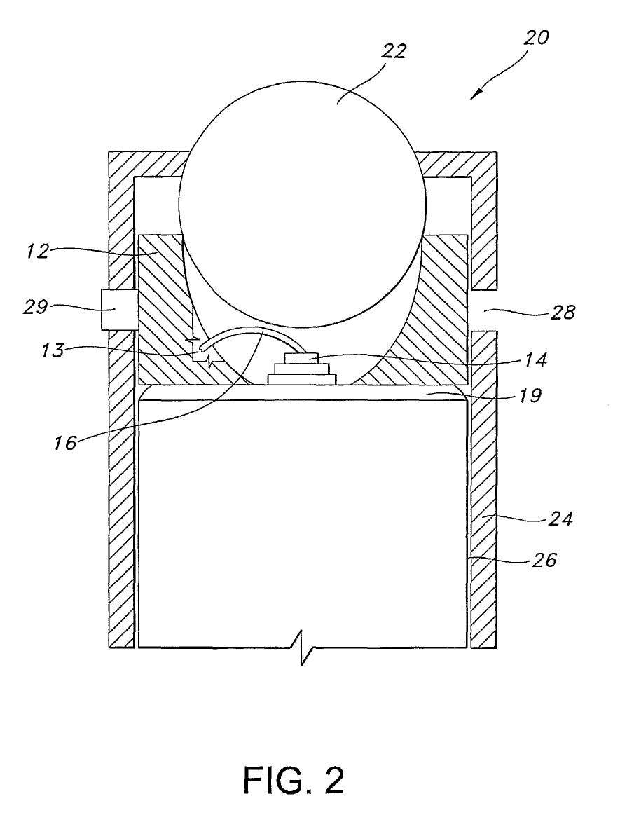

Referring to FIG. 2, there is shown a schematic cut-away side view of LED electro-optic assembly 20 with the LED-reflector assembly 10 of the present invention. The optical components include a lens 22 that directs the light generated by the LED chip 14 by focusing the light to a desired spot size by collimating the light to a desired location. The lens 22 may be attached or molded precisely in the assembly so that it is centered at the collimated beam. The shape and/or size of the lens 22 may vary to shape the conical beam of light emitted from the LED assemblies to provide the desired optical illumination pattern.

The optical lens 22 in shape of a ball is partially located in the reflector 12 of the upper electrode 10a as shown in FIG. 3. Even though a ball shaped optic lens 22 is shown in the present invention, it is understood that other different shapes of optics can be selected. The optics can be varied depending on the desired output. In the present invention, ball optic 22 is selected in order to produce the maximum light power density with the available LED output. The LED output is focused to a desired spot just outside the ball optic lens 22. If a collimated beam is desired, a half ball optical lens a parabolic optical lens shown may desirably be used. Additionally, the positioning of the lens 22 may also vary depending on the size of the work piece to be illuminated.

The number of LED assemblies employed determines the size of a LED array and the desired output intensity. An end user can easily increase or decrease the output intensity by adding/removing LED assemblies to/from the LED array. Also, a user can change the operating wavelength of the assembly by replacing one or more LED assemblies of a first operating wavelength with one or more replacement assemblies having a second wavelength. In addition, a user can replace damaged or expired LED assemblies without replacing the entire LED array.

Regarding the electro optical properties of the optical assembly 20, each LED 14, emits diffuse light at a predetermined optical power and a predetermined optical wavelength. Exemplary LEDs 14 according to the present invention emit preferably greater than 500 mw of optical power at desirably 405 nm. The reflective cavity collimates a majority of the diffuse light emitted by the LED 14 when the LED 14 is placed at the desired location within the reflective cavity. The reflector 12 represents an exemplary reflective cavity that collimates the majority of the light when the LED 14 is placed at or near the focal point of elliptic reflector 12, as shown in FIG. 3. It will be understood by those skilled in the art that the collimating means of the present invention is not limited to an elliptical reflector 12. Other LED collimating means well understood by those skilled in the art may also be implemented in the present invention.

Furthermore, in order to hold the optic lens 22 in place and also provide a path for electrical conduction a generally cylindrical electric sleeve 24 is provided in the LED electro optic assembly 24 of FIG. 3. The outside of the sleeve 24 is masked to allow contact with an external electrical connection. The sleeve 24 preferably made of aluminum is coated with electrical insulating coating 26 such as a non-conductive adhesive. The reflector 12 is preferably bonded to the thermal heat sink 18 with the non-conductive adhesive 24. The sleeve 24 includes two slots or passages 28 therethrough adjacent to the reflector 12. These passages 28 are preferably machined into the sleeve 24 after the sleeve 24 is coated. The two passages 28 provide four open spaces to make contact with the sleeve 24, thereby maximizing the electrical conductivity. Additionally, a conductive adhesive is applied to the passages 28 to bond the outside sleeve 24 to the reflector 12 inside the assembly 30 and the outside sleeve 24. In order to clearly illustrate only one passage 28 and one adhesive 29 is shown, however, multiple passages 28 and more than one adhesive 29 is applied to the passages 28. Alternatively, a wire, preferably aluminum (not shown) may be used to wire bond between the reflector 12 inside the assembly and the outside sleeve 24 preferably made of aluminum. Multiple wire bonds are desirably used to bond the reflector 12 and a recess (not shown) below the surface of the outside sleeve 24. Also, the recess is desirably coated for protection. The conductive material is heat cured and the complete LED electro-optic assembly 20 is formed.

Individual alignment of the LED 14 or multiple LEDs is required because no two individual LED assemblies are exactly the same. Differences arise from the positioning of the chip 14 inside the reflector 12, the positioning of the reflector cup 12, the positioning of the electrodes 10a and 10b, and the positioning of the optic lens 22. All of these factors affect the geometry and direction of the beam of light. Due to the manufacturing process of individual LED assemblies, the components in individual LED assemblies exhibit a very wide range of positional relationships. Therefore, for any application that requires illumination of a specific area, each individual LED assembly must be manually aligned and then permanently held in place by some means of mechanical support.

While a single LED is used herein to illustrate the invention, it will be understood by those skilled in the art that the invention described herein applies to a plurality of LEDs or LED array. A plurality of LEDs may be arranged in any manner as desired for illumination.

Even though, in the present invention the LED 14 is shown to be a rectangular frame, those of ordinary skill in the art will understand that according to the disclosed invention, LED illuminators may be formed in any shape suitable to provide light for a wide array of applications, including but not limited to photocuring, video, shop windows, photography or specialty product displays. Because of the durability and rugged construction of the disclosed LED illuminator, it may be used in outdoor settings, marine applications, or hostile environments.

Similar to the LED assembly of FIG. 1, the LED electro-optic assembly of FIG. 2 shows the LED 14 bonded to the heat sink 18 via the bond material 19. Again, the top surface of the LED 14 is directly bonded to the cut 13 on the side wall 12a the reflector 12 via the aluminum wire 16. This direct connection of the LED 14 to the reflector 12 provides high output LED assembly with the desired optical illumination pattern.

Individual alignment of the LED 14 or multiple LEDs is required because no two individual LED assemblies are exactly the same. Differences arise from the positioning of the chip 14 inside the reflector 12, the positioning of the reflector cup 12, the positioning of the electrodes 10a and 10b, and the positioning of the optic lens 22. All of these factors affect the geometry and direction of the beam of light. Due to the manufacturing process of individual LED assemblies, the components in individual LED assemblies exhibit a very wide range of positional relationships. Therefore, for any application that requires illumination of a specific area, each individual LED assembly must be manually aligned and then permanently held in place by some means of mechanical support.

While a single LED is used herein to illustrate the invention, it will be understood by those skilled in the art that the invention described herein applies to a plurality of LEDs or LED array. A plurality of LEDs may be arranged in any manner as desired for illumination.

Even though, in the present invention the LED 14 is shown to be a rectangular frame, those of ordinary skill in the art will understand that according to the disclosed invention, LED illuminators may be formed in any shape suitable to provide light for a wide array of applications, including but not limited to photocuring, video, shop windows, photography or specialty product displays. Because of the durability and rugged construction of the disclosed LED illuminator, it may be used in outdoor settings, marine applications, or hostile environments.

While a single LED is used herein to illustrate the invention, it will be understood by those skilled in the art that the invention described herein applies to a plurality of LEDs or LED array. A plurality of LEDs may be arranged in any manner as desired for illumination.

Even though, in the present invention the LED 14 is shown to be a rectangular frame, those of ordinary skill in the art will understand that according to the disclosed invention, LED illuminators may be formed in any shape suitable to provide light for a wide array of applications, including but not limited to photocuring, video, shop windows, photography or specialty product displays. Because of the durability and rugged construction of the disclosed LED illuminator, it may be used in outdoor settings, marine applications, or hostile environments.

1. A LED assembly comprising:
at least one LED;
a heat sink supporting said LED in electrical engagement therewith;
a conductive reflector mounted to the heat sink and in electrical engagement with said LED;
a wire attached from the LED to said cut on the reflector; and
an insulative member electrically isolating said conductive reflector from said heat sink, wherein said heat sink and said reflector form an electrically conductive location for supplying power to said LED.

2. The assembly of claim 1 wherein one end of the wire is welded to top surface of said LED and other end of the wire is soldered to the cut on the reflector.

3. The assembly of claim 1 wherein said wire is constructed from an aluminum containing material.

4. The assembly of claim 1 wherein said reflector is constructed from an aluminum-containing material.

5. The assembly of claim 1 wherein said reflector provides an electrical transfer path away from said chip.

6. The assembly of claim 1 wherein said heat sink includes a planar surface at one end and wherein said LED is mounted to said surface.

7. The assembly of claim 1 wherein said reflector is an elliptical reflector having a central opening therethrough and wherein said LED is mounted in said central opening.

8. The assembly of claim 1 wherein said insulative member includes a bonding agent for securing said conductive reflector to said heat sink.

9. The assembly of claim 1 wherein said heat sink is a heat pipe.

10. The assembly of claim 1 further including:
an optic lens member positioned adjacent to said reflector, said optic lens member being spaced from said LED for focusing light rays emanating from said LED.

11. The assembly of claim 10 wherein said optic lens member is supported at least partially within said reflector.

12. The assembly of claim 10 further including a conductive retaining sleeve supporting said heat sink, said reflector and said optic lens member.

13. The assembly of claim 12 wherein said conductive sleeve is placed in electrical continuity with said conductive reflector.

14. The assembly of claim 12 wherein said conductive sleeve is insulatively separated from said heat pipe.

15. The assembly of claim 12 wherein said sleeve includes at least one passage therethrough adjacent said conductive reflector.

16. The assembly of claim 15 wherein said passage is filled with a conductive adhesive to establish conductive engagement between said sleeve and said reflector.

17. The assembly of claim 15 which said passage is electrically engaged with said sleeve and said reflector.

18. A method of forming a high output LED assembly comprising the steps of:
conductively attaching at least one LED to a heat sink;
providing said LED adjacent a conductive reflector; and
wire bonding said LED to said cut on the reflector.

19. The method of claim 18 further including:
disposing an insulative bonding agent between the reflector and the heat sink.

20. The method of claim 18 wherein said reflector is constructed from an aluminum containing material.

21. The method of claim 18 wherein said wire is constructed from an aluminum containing material.

22. The assembly of claim 1 wherein said reflector includes a side wall having a cut in a portion thereof and wherein said wire is bonded from said LED to said cut on said reflector.

23. The assembly of claim 22 wherein said cut is machined into said portion of said side wall.

24. The assembly of claim 1 wherein said reflector surrounds said LED.

25. A method of claim 18 wherein said providing step further includes:
surrounding said LED with said conductive reflector.

26. A method of claim 18 further including the step of:
machining a cut in a side wall of said reflector.

27. A method of claim 26 wherein said wire bond step further includes:
wire bonding said LED to said cut in said reflector.
